(19) United States
(12) Patent Application Publication
(10) Pub. No.: US 2019/0308270 A1
(43) Pub. Date: Oct. 10, 2019

(54) SYSTEMS FOR LASER ASSISTED METALLIZATION OF SUBSTRATES

(71) Applicant: SunPower Corporation, San Jose, CA (US)

(72) Inventors: Pei Hsuan Lu, San Jose, CA (US); Benjamin I. Hsia, Fremont, CA (US); George G. Correos, Corralitos, CA (US)

(21) Appl. No.: 16/377,077

(22) Filed: Apr. 5, 2019

Related U.S. Application Data
(63) Continuation-in-part of application No. 16/376,802, filed on Apr. 5, 2019.
(60) Provisional application No. 62/773,172, filed on Nov. 29, 2018.
(60) Provisional application No. 62/773,168, filed on Nov. 29, 2018.
(60) Provisional application No. 62/773,148, filed on Nov. 29, 2018.
(60) Provisional application No. 62/654,198, filed on Apr. 6, 2018.

(51) Int. Cl. B23K 26/22; H01L 31/18; B23K 26/00; B23K 26/02; B23K 26/08; B23K 26/10; B23K 26/06; B23K 26/16

(52) U.S. Cl. CPC B23K 26/22; H01L 31/18; B23K 26/0006; B23K 26/02; H01L 31/02008; B23K 26/10; B23K 26/0608; B23K 26/16; B23K 26/0876

(57) ABSTRACT

A system for fabricating solar cells. The system including one or more of: a laser assisted metallization patterning unit adapted to expose a metal foil located over a substrate to a laser beam to form a conductive contact structure comprising a locally deposited metal on the substrate; a debris removal unit adapted to remove debris from a top surface of a metal foil that is attached to a top surface of a substrate; a carrier attachment unit adapted to attach a carrier to one the top surface of the metal foil; and a metal removal unit adapted to remove the carrier and at least a portion of the metal foil.

### CROSS-REFERENCE TO RELATED APPLICATIONS

This application claims the right of priority to and benefit of earlier filing date of U.S. Provisional Application No. 62/773,172, filed on Nov. 29, 2018, U.S. Provisional Application No. 62/773,168, filed on Nov. 29, 2018, U.S. Provisional Application No. 62/773,148, filed on Nov. 29, 2018, and U.S. Provisional Application No. 62/654,198, filed on Apr. 6, 2018, each of which is hereby incorporated by reference herein in its entirety. This application also claims the right of priority to and benefit of earlier filing of U.S. patent application Ser. No. 16/376,802, filed Apr. 5, 2019, titled “Local Metallization for Semiconductor Substrates using a Laser Beam,” Attorney Docket No. 131815-244461_P270US, SunPower Ref. No. 52040US, which is hereby incorporated by reference in its entirety.

### TECHNICAL FIELD

Embodiments of the present disclosure are in the field of renewable energy or semiconductor processing and, in particular, to systems, tools and methods of forming solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Electrical conversion efficiency is an important characteristic of a solar cell as it is directly related to the capability of the solar cell to generate power; with higher efficiency providing additional value to the end customer; and, with all other things equal, higher efficiency also reduces manufacturing cost per Watt. Likewise, simplified manufacturing approaches provide an opportunity to lower manufacturing costs by reducing the cost per unit produced. Accordingly, techniques for increasing the efficiency of solar cells and techniques for simplifying the manufacturing of solar cells are generally desirable.

### BRIEF DESCRIPTION OF THE DRAWINGS

FIG. 1 illustrates a plan view schematic of a system for a laser assisted metallization patterning (LAMP) of substrates.

FIG. 2 illustrates an exemplary work flow for LAMP of substrates.

FIG. 3 illustrates a schematic of a laser assisted metal patterning unit.

FIG. 4 illustrates an exemplary work flow for LAMP of substrates.

FIG. 5A illustrates a schematic of a brush design for removing debris from a solar cell.

FIG. 5B illustrates a plan view of the removal of debris from a solar cell.

FIG. 5C illustrates a plan view of the removal of debris from a solar cell.

FIG. 6A illustrates a plan view of an oscillating brush design for the removal of debris from a solar cell.

FIG. 6B illustrates an elevation view of the oscillating brush design of FIG. 6A.

FIG. 6C illustrates an elevation view of the oscillating brush design of FIG. 6A demonstrating brush oscillation.

FIG. 6D illustrates a schematic of an oscillating brush design for the removal of debris from a solar cell.

FIG. 7 illustrates a perspective view of an oscillating brush debris removal unit of a system for fabricating a solar cell.

FIG. 8A illustrates a perspective view of a roller brush head for a debris removal unit of a system for fabricating a solar cell.

FIG. 8B illustrates a side elevation view of a roller brush head of FIG. 8A for a debris removal unit of a system for fabricating a solar cell.

FIG. 9A illustrates a perspective view of a roller brush debris removal unit of a system for fabricating a solar cell.

FIG. 9B illustrates a perspective view of a roller brush debris removal unit of a system for fabricating a solar cell.

FIG. 10 illustrates an exemplary work flow for metal removal from a substrate.

FIG. 11 illustrates a schematic of a laser assisted metal patterning unit.

FIGS. 12A-12C illustrates a schematic of a metal removal system.

FIGS. 13A-13C illustrates a schematic of a metal removal system.

FIGS. 14A-14F illustrate side elevation views of various operations in a method of LAMP of substrates.

FIGS. 15A-15E illustrate side elevation views of various operations in a method of LAMP of substrates.

FIGS. 16A-16E illustrate side elevation views of various operations in a method of LAMP of substrates.

FIGS. 17A-17C illustrate a schematic of foil removal using an expanding mandrel.

### DETAILED DESCRIPTION

The following detailed description is merely illustrative in nature and is not intended to limit the embodiments or the application and uses of such embodiments. As used herein, the word “exemplary” means “serving as an example, instance, or illustration.” Any implementation described herein as exemplary is not necessarily preferred or advantageous over other implementations. Furthermore, there is no intention to be bound by any expressed or implied theory presented in the preceding technical field, background, brief summary or the following detailed description.

References to “one embodiment” or “an embodiment” do not necessarily refer to the same embodiment. Particular features, structures, or characteristics can be combined in any suitable manner consistent with this disclosure.

Terminology. The following paragraphs provide definitions and/or context for terms found in this disclosure (including the appended claims):

“Regions” or “portions” describe discrete areas, volumes, divisions or locations of an object or material having definable characteristics but not always fixed boundaries.

“Comprising” is an open-ended term that does not foreclose additional structure or steps.

“Configured to” connotes structure by indicating a device, such as a unit or a component, includes structure that performs a task or tasks during operation, and such structure is configured to perform the task even when the device is not currently operational (e.g., is not on/active). A device “configured to” perform one or more tasks is expressly intended to not invoke a means or step plus function interpretation under 35 U.S.C. §112, (f) or sixth paragraph.

“First,” “second,” etc. terms are used as labels for nouns that they precede, and do not imply any type of ordering (e.g., spatial, temporal, logical, etc.). For example, reference to a “first” solar cell does not necessarily mean such solar cell is the first solar cell in a sequence; instead the term “first” is used to differentiate this solar cell from another solar cell (e.g., a “second” solar cell).

“Coupled” refers to elements, features, structures or nodes, unless expressly stated otherwise, that are or can be directly or indirectly joined or in communication with another element/node/feature, and not necessarily directly mechanically joined together.

“Inhibit” describes reducing, lessening, minimizing or effectively or actually eliminating something, such as completely preventing a result, outcome or future state completely.

“Exposed to a laser beam” describes a process subjecting a material to incident laser light, and can be used interchangeably with “subjected to a laser,” “processed with a laser” and other similar phrases.

“Doped regions,” “semiconductor regions,” and similar terms describe regions of a semiconductor disposed in, on, above or over a substrate. Such regions can have a N-type conductivity or a P-type conductivity, and doping concentrations can vary. Such regions can refer to a plurality of regions, such as first doped regions, second doped regions, first semiconductor regions, second semiconductor regions, etc. The regions can be formed of a polycrystalline silicon on a substrate or as portions of the substrate itself.

“Thin dielectric layer,” “tunneling dielectric layer,” “dielectric layer,” “thin dielectric material” or intervening layer/material refers to a material on a semiconductor region, between a substrate and another semiconductor layer, or between doped or semiconductor regions on or in a substrate. In an embodiment, the thin dielectric layer can be a tunneling oxide or nitride layer of a thickness of approximately 2 nanometers or less. The thin dielectric layer can be referred to as a very thin dielectric layer, through which electrical conduction can be achieved. The conduction can be due to quantum tunneling and/or the presence of small regions of direct physical connection through thin spots in the dielectric layer. Exemplary materials include silicon oxide, silicon dioxide, silicon nitride, and other dielectric materials.

“Intervening layer” or “insulating layer” describes a layer that provides for electrical insulation, passivation, and inhibit light reflectivity. An intervening layer can be several layers, for example a stack of intervening layers. In some contexts, the intervening layer can be interchanged with a tunneling dielectric layer, while in others the intervening layer is a masking layer or an “antireflective coating layer” (ARC layer). Exemplary materials include silicon nitride, silicon oxynitride, silicon oxide (SiOx) silicon dioxide, aluminum oxide, amorphous silicon, polycrystalline silicon, molybdenum oxide, tungsten oxide, indium tin oxide, tin oxide, vanadium oxide, titanium oxide, silicon carbide and other materials and combinations thereof. In an example, the intervening layer can include a material that can act as a moisture barrier. Also, for example, the insulating material can be a passivation layer for a solar cell. In an example the intervening layer can be a dielectric double layer, such as a silicon oxide (SiOₓ), for example with high hydrogen content, aluminum oxide (Al₂O₃) dielectric double layer.

“Locally deposited metal” and “metal deposition” are used to describe forming a metal region by exposing a metal source to a laser that forms and/or deposits metal from the metal source onto portions of a substrate. This process is not limited to any particular theory or mechanism of metal deposition. In an example, locally deposited metal can be formed upon exposure of a metal foil to a laser beam that forms and/or deposits metal from the metal foil, such as all of the metal foil exposed to the laser beam, onto portions of a silicon substrate. This process can be referred to as a “Laser Assisted Metallization Patterning” or LAMP technique. The locally deposited metal can have a thickness of 1 nanometers (nm) to 20 microns (μm), a width approximately defined by the laser beam size, and physical and electrical properties matching those of the source metal foil.

“Patterning” refers to a process of promoting separation or separating portions of a source metal, and can specifically refer to weakening a region of a metal foil that is between a bulk of the metal foil and a deposited region of the metal foil (i.e., the deposited metal). This patterning can be the result of heat, perforation, deformation or other manipulation of the metal foil by the same laser process, LAMP, that deposits a metal foil onto a substrate, and can promote removal of the bulk of the metal foil (i.e., the non-deposited metal foil) from the resulting device. Unless expressed otherwise, references to LAMP includes such patterning.

“Substrate” can refer to, but is not limited to, semiconductor substrates, such as silicon, and specifically such as single crystalline silicon substrates, multi-crystalline silicon substrates, wafers, silicon wafers and other semiconductor substrates used for solar cells. In an example, such substrates can be used in micro-electronic devices, photovoltaic cells or solar cells, diodes, photo-diodes, printed circuit boards, and other devices. These terms are used interchangeably herein. A substrate also can be glass, a layer of polymer or another material.

“About” or “approximately”. As used herein, the terms “about” or “approximately” in reference to a recited numeric value, including for example, whole numbers, fractions, and/or percentages, generally indicates that the recited numeric value encompasses a range of numerical values (e.g., +/−5% to 10% of the recited value) that one of ordinary skill in the art would consider equivalent to the recited value (e.g., performing substantially the same function, acting in substantially the same way, and/or having substantially the same result).

In addition, certain terminology can also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology can include the words specifically mentioned above, derivatives thereof, and words of similar import.

In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as emitter region fabrication techniques, are not described in detail in order to not unnecessarily obscure embodiments of the present disclosure. Furthermore, it is to be appreciated that the various embodiments shown in the figures are illustrative representations and are not necessarily drawn to scale.

Disclosed herein are systems, units, and methods for the metallization of a solar cell substrates, such as for the metallization of a solar cell substrates. The disclosed systems, units, and methods described herein can be applicable for interdigitated back contact (IBC) solar cells as well as other types of solar cells including continuous emitter back contact solar, front and/or back contact solar cells having a trench architecture, e.g. were the n-type and p-type doped regions are separated by a trench structure, thin-film solar cells, Heterojunction with Intrinsic Thin layer (HIT) Solar cells, Tunnel Oxide Passivated Contact (TOPCon) Solar Cells, organic and front-contact solar cells, front contact cells having overlapping cell sections, Passivated Emitter and Rear Cell (PERC) solar cells, mono-PERC solar cells, laminates and other types of solar cells.

The systems, units, and methods described herein can be applicable for solar cells having a plurality of subcells coupled by metallization structures. In an embodiment, a groove can be located between adjacent sub-cells and a metallization structure can connect the adjacent sub-cells together. In an embodiment, the groove can singulate and physically separate one sub-cell from another, e.g., adjacent, sub-cell. In an embodiment, the metallization structure can physically and electrically connect the sub-cells, where the metallization structure can be located over the groove.

The systems, units, and methods described herein can also be applied to solar cells and/or solar cell portions which have been singulated and/or physically separated, e.g., diced, partially diced and further separated. In an example, these solar cells and/or solar cell portions can be joined together, either physically and/or electrically, by the metallization structures and processes described herein.

The systems, units, and methods described herein can also be applicable for micro-electronic, semiconductor devices and other substrates in general, such as light emitting diodes, microelectromechanical systems and others. Embodiments described herein can be distinguished over a laser induced forward transfer (LIFT) process, where a film is deposited on glass and requires subsequent plating or the like to achieve a desired metal thickness.

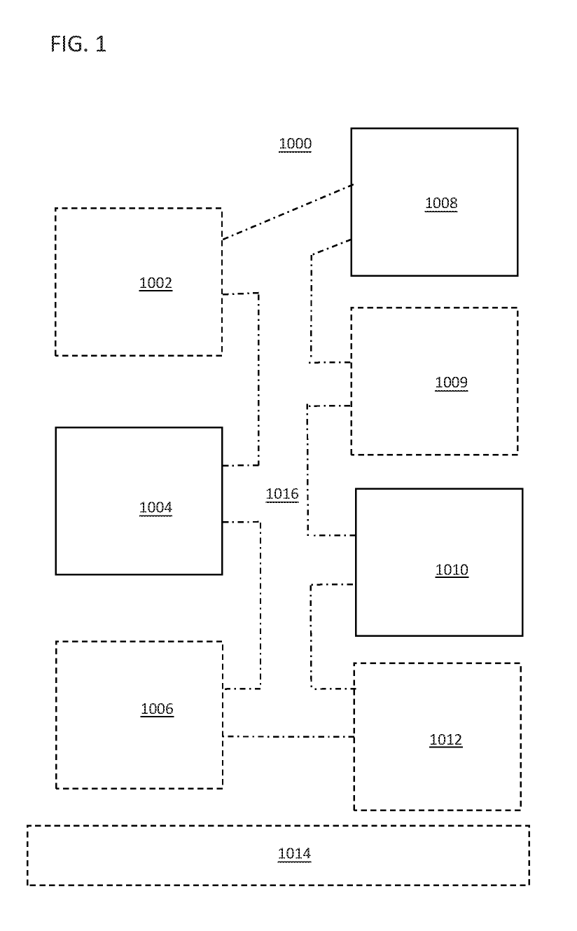

FIG. 1 is a plan view that schematically shows a substrate metallization system 1000, in accordance with embodiments of the present disclosure. The individual units of the system will become apparent in the following discussion. In an example, the substrates can include silicon substrates. In an example, the substrates can be solar cells substrates. In the example, the metallization system 1000 includes a laser assisted metallization patterning (LAMP) unit 1004, optionally a debris removal unit 1006, a carrier attachment unit 1008, optionally one or more additional laser assisted metallization patterning units 1009, a metal removal unit 1010, and/or as other additional optional metallization units 1012. In an example, the optional metallization unit 1012 can include a metallization unit for coupling together a plurality of substrates, etc. The substrate metallization system 1000 can also include a control system 1014. In an example, the control system 1014 can control aspects of at least one or more of the other units. In one example, the substrates can be delivered to the system that have already had metal foil attached, for example, attached in another system, unit and/or method. In an example, the substrates can be delivered to the system can already include a plurality of conductive contact structures, each conductive contact structure including a locally deposited metal portion that is in electrical connection with the substrate.

In addition, the substrate metallization system 1000 can include other units 1002 as desired. The other units can include, for example, a metal deposition tool (e.g., a metal seed deposition tool). In an embodiment, the substrate metallization system 1000 can include transport mechanisms 1016 for moving substrates through the different units of the substrate metallization system 1000. In some embodiments, different transport mechanisms are used for transporting work pieces between stations. As one non-limiting example, a linear conveyor can be used, having one or more work piece supports in the form of chucks. Typically, a chuck can be configured to hold and support a single solar cell wafer. In an example, a chuck can secure the wafer to prevent it from moving while cycling through the units. In one example, the transport system includes a linear conveyor, such as a vacuum linear conveyor. In an example, the vacuum linear conveyor removes the need for a chuck as substrates are held down and moved by the vacuum linear conveyor. In an example, the transport system can include an automated work piece handler, such as a pick and place robot, which can be used to load and unload wafers to and from the units of the substrate metallization system 1000. The substrate metallization system 1000 can also include additional units and tools, for example for the cutting and/or placement of metal foil and/or carriers as described herein. Such additional tools and/or units can be stand alone or integrated into the units detailed herein.

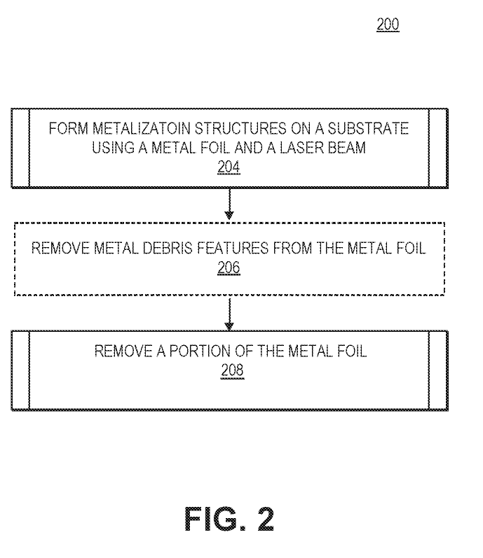

To provide context, FIG. 2 is a flowchart 200 representing various operations in a method of a laser assisted metallization pattering (LAMP) of substrates in accordance with an embodiment of the present disclosure. In an example, the substrate metallization system 1000 described above can be used in a method of producing a metallized substrate, such as a solar cell. Beginning at operation 204, in an example, the method involves forming metallization structures, such as conductive contact structures having a locally deposited metal portion in electrical contact with a substrate, for example, using a metal foil and a laser beam, using a laser assisted metallization patterning unit 1004. Optionally, at operation 206, the method involves removing metal debris features from the metal foil. In an example, removing metal debris can include using the debris removal unit 1006. At operation 208, in an example, the method involves removing a portion of the metal foil, for example using a metal removal unit 1010. In an example, the metal foil removed can be metal foiled not exposed to the laser beam. In some examples, the metal foil removed can include metal foil exposed, instead, to another different laser beam, e.g., a laser beam of different properties (e.g., power, wavelength, frequency, etc.).

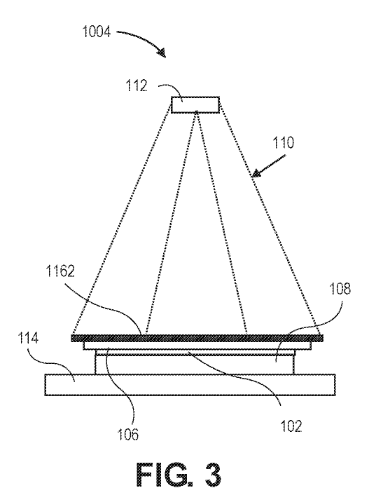

FIG. 3 illustrates a schematic elevation view of a laser assisted metallization patterning (LAMP) unit 1004, according to some embodiments. In an example, the LAMP unit 1004 can include a laser source 112 and a platform, such as a chuck 114, for example, to position a work piece undergoing LAMP. A substrate 108 can be located on the chuck 114. In an example, the substrate 108 can include a semiconductor substrate and/or a solar cell. In an embodiment, the substrate 108 can include an intervening layer 102. In an embodiment, the intervening layer 102 can include openings exposing portions of the substrate 108. In an example, the contact openings in the intervening layer 102 can expose doped regions (e.g., N-type or P-type doped regions) in or above the substrate 108. In one example, the doped regions can include doped polysilicon regions. In embodiments, intervening layer 102 can be formed with openings (e.g., patterned as deposited), or openings are formed in a blanket-deposited intervening layer 102. In the latter case, in one embodiment, openings are formed in intervening layer 102 by patterning with laser ablation and/or a lithography and etch process, such as process can occur with the LAMP unit 1004 or elsewhere. In an embodiment, the LAMP unit 1004 is configured to deposit and pattern the intervening layer 102, or just pattern intervening layer 102. While reference is made to forming the intervening layer on or above the substrate it is appreciated that the direction above is relative and that this intervening layer can be formed on the back, the front, or even the back and the front, of a selected substrate, for example, for metallization of the front, back, or both the front and back of the substrate.

In one embodiment, the LAMP unit 1004 is adapted to locate or place a metal foil 106 over an intervening layer 102. Alternatively, the substrate metallization system 1000 can include a pick and place robot which can place the metal foil 106 over the intervening layer 102. In an embodiment, at the time of locating the metal foil 106 and the substrate 108, the metal foil 106 can have a surface area substantially larger than a surface area of the solar cell 100. In an embodiment, however, prior to placing the metal foil 100 over the solar cell, a large sheet of foil can be cut to provide the metal foil 106 having a surface area substantially the same as the surface area of the substrate 100. The metal foil 106 can be laser cut, water jet cut, and the like, for example, prior to or even after placement over, on or above the substrate 108. In one embodiment, the LAMP unit 1004 can include a vacuum to secure or uniformly locate the metal foil 106 over the substrate 108. In an example, using a vacuum can allow there to be no air gaps or spaces between the metal foil 106 and the substrate 108. In an embodiment, the LAMP unit 1004 can include an alignment system to accurately locate the metal foil 106 over the substrate 108. In one embodiment, the LAMP unit 1004 can include a roller, where the roller can be used to position or locate the metal foil 106 over the substrate 108. In an example, similar to the vacuum, the roller can uniformly locate the metal foil 106 over the substrate 108, e.g., no air gaps or spaces between the metal foil 106 and the substrate 108.

An exemplary aluminum (Al) metal foil has a thickness approximately in the range of 1-100 μm, for example in the range of 1-15 μm, 5-30 μm, 15-40 μm, 25-50 μm 30-75 μm, or 50-100 μm. The Al metal foil can be a temper grade metal foil such as, but not limited to, F-grade (as fabricated), O-grade (full soft), H-grade (strain hardened) or T-grade (heat treated). The aluminum metal foil can be anodized or not, and can include one or more coatings. Multilayer metal foils can also be used. Exemplary metal foils include metal foils of aluminum, copper, tin, tungsten, manganese, silicon, magnesium, zinc, lithium and combinations thereof with or without aluminum in stacked layers or as alloys. In an embodiment, the metal foil comprises a continuous sheet, for example a continuous sheet that can cover the entire substrate 108, including one or more of the openings in the intervening layer 102. In other embodiments, the metal foil can cover a portion of the substrate 108, such as a portion including one or more of the openings in the intervening layer 102. In an embodiment, the intervening layer 102 can be formed to cover the entire surface, on and/or above, of the substrate 108. In an embodiment, the intervening layer 102 can be formed only partially covering the surface, over, on and/or above, of the substrate 108.

In one embodiment, the LAMP unit 1004 is adapted to expose the metal foil to a laser beam 110 in locations over, partially over, offset from and/or adjacent to the openings in the intervening layer 102. In an example, the laser source 112 can be used to expose the metal foil 106 to a laser beam 110. In an embodiment, the power, wavelength and/or pulse duration of a laser beam 110 can be selected to form the plurality of conductive contact structures electrically connected to the substrate, each conductive contact structure including a locally deposited metal portion. The power, wavelength and/or pulse duration of a laser are so as not to fully ablate the foil, but rather as mentioned above, provide the energy to deposit a portion of the metal foil onto the substrate. In an example, the power, wavelength and/or pulse duration of a laser for a LAMP technique are selected so as to form a plurality of locally deposited metal portions, but not to fully ablate the foil. The power, wavelength and/or pulse duration can be selected/tuned based on the metal foil composition, melting temperature and/or thickness. In an example, the laser has a wavelength of between about 250 nm and about 2000 nm (such as wavelength of 250 nm to 300 nm, 275 nm to 400 nm, 300 nm to 500 nm, 400 nm to 750 nm, 500 nm to 1000 nm, 750 nm to 1500 nm, or 1000 nm to 2000 nm), the laser peak power is above 5×10⁺⁴ W/mm², and the laser is a pulse laser with a pulse frequency of about 1 kHz and about 10 MHz (such as about 1 kHz and about 10 MHz, such a 1 kHz to 1000 kHz, 500 kHz to 2000 kHz, 1000 kHz to 5000 kHz, 2000 kHz to 7500 kHz, or 5000 kHz to 10 mHz. The pulse duration can be between 1 fs to 1 ms, such as 1 fs to 250 fs, 100 fs to 500 fs, 250 fs to 750 fs, 500 fs to 1 ns, 750 fs to 100 ns, 1 ns to 250 ns, 100 ns to 500 ns, 250 ns to 750 ns, 500 ns to 1000 ns, 750 ns to 1500 ns, 1000 ns to 5000 ns, 1500 ns to 10000 ns, 5000 ns to 100000 ns, 10000 ns to 500000 ns, and 100000 to 1 ms. The laser can be an IR, Green or a UV laser. In certain examples, the laser beam has a width of between about 20 μm and about 50 μm, such as 20-30 μm, 25-40 μm, and 30-50 μm.

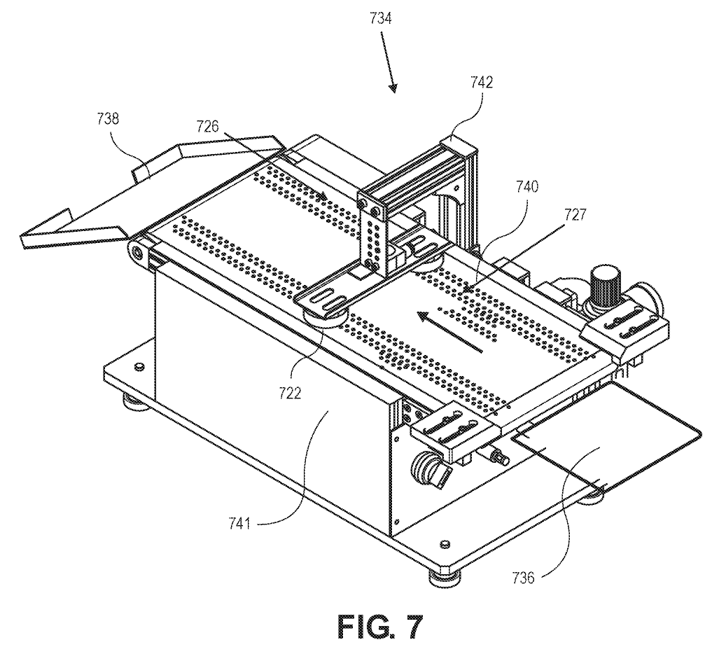

Referring again to FIG. 3, the laser source 112 can generate a laser beam 110 directed to scan onto the substrate 108. In the example as shown, the substrate 108 is located on the chuck 114. In one example, the chuck 114 can include a vacuum chuck. In some examples, the substrate 108 can be placed or located on a vacuum conveyer belt, e.g., referring to FIG. 7. In an embodiment, the laser beam can be split, for example, using a beam splitter or other optical/mirror arrangement. In an example, the laser source 112 can be a commercially available laser source. In an embodiment, the LAMP unit 1004 can be controlled by an integrated controller (not shown). In one embodiment, the LAMP unit 1004 can be controlled by the control system 1014.

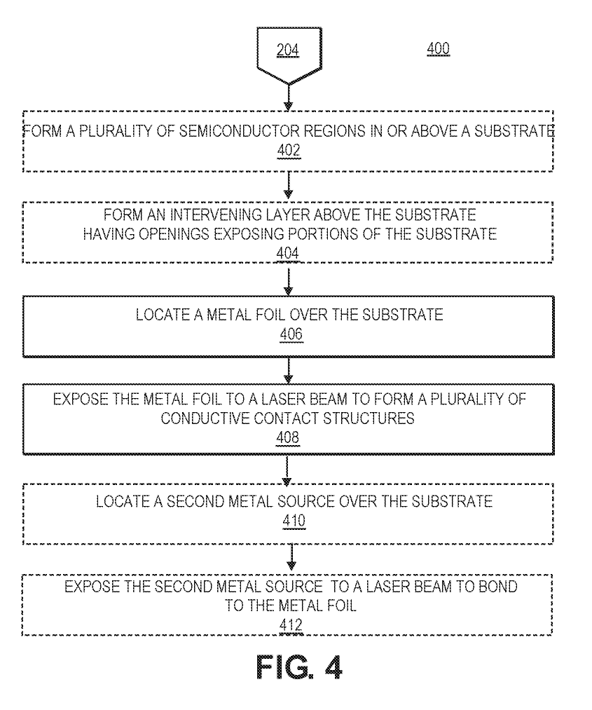

FIG. 4 is a flowchart 400 representing various operations of forming metallization structures on a substrate in operation 204 of the work flow of FIG. 2, for example, using a laser assisted metallization patterning (LAMP) unit 1004, in accordance with an embodiment of the present disclosure. At optional operation 402, the method can include forming a plurality of semiconductor regions in or above a substrate. In an example, semiconductor regions can be N-type and P-type doped polysilicon regions and the substrate can include a solar cell. At optional operation 404, the method can include forming an intervening layer above the substrate. In some examples, the intervening layer can have openings exposing portions of the substrate. At operation 406, the method involves locating a metal foil over the substrate. At operation 408, the method involves exposing the metal foil to a laser beam, wherein exposing the metal foil to the laser beam can form a plurality of conductive contact having locally deposited metal portions, the locally deposited metal portions can be electrically connected to the substrate. At optional operation 410, the method involves locating a second metal source over the substrate, for example over the foil and/or the plurality of conductive contact having locally deposited metal portions. In an embodiment, the second metal source is located as described above, with respect to locating the metal foil. Operation 410 can occur, for example, using a laser assisted metallization patterning (LAMP) unit 1004, or, for example using the carrier attachment unit 1008, optionally one or more additional laser assisted metallization patterning units 1009. In an example the second metal source is a metal foil, such as described above. In another example the second metal source is a metal wire or a metal tape. At optional operation 412, the method involves exposing the second metal source to a laser beam, wherein exposing the second metal source to the laser beam bonds the second metal source to the foil and/or the plurality of conductive contact having locally deposited metal portions. Subjecting the second metal source to the laser beam can connect the second metal source to the first metal foil. Removing the second metal source from the substrate can selectively remove regions of the first metal foil that are not connected to semiconductor regions on the substrate. In an embodiment, the second metal source is further used to provide additional metallization to a solar cell, for example to build or provide another or second layer or more layers of metal in selected regions of the metallization, such as for the construction of busbars were addition metal thickness could prove useful for conduction of electricity. Thus, in an embodiment, laser assisted metallization patterning (LAMP) unit 1004, the carrier attachment unit 1008, or one or more optional additional LAMP units 1009 is adapted to bond the second metal source to the first metal foil in selected regions to provide additional metallization in these selected regions. In embodiments, the laser assisted metallization patterning (LAMP) unit 1004, the carrier attachment unit 1008, or one or more optional additional LAMP units 1009 is adapted to pattern the second metal source, for example to increase metal thickness in some regions and to be used as a carrier to remove the first metal foil in other regions. In an example, the laser has a wavelength of between about 250 nm and about 2000 nm (such as wavelength of 250 nm to 300 nm, 275 nm to 400 nm, 300 nm to 500 nm, 400 nm to 750 nm, 500 nm to 1000 nm, 750 nm to 1500 nm, or 1000 nm to 2000 nm), the laser peak power is above 5×10⁺⁴ W/mm², and the laser is a pulse laser with a pulse frequency of about 1 kHz and about 10 MHz (such as about 1 kHz and about 10 MHz, such a 1 kHz to 1000 kHz, 500 kHz to 2000 kHz, 1000 kHz to 5000 kHz, 2000 kHz to 7500 kHz, or 5000 kHz to 10 mHz. The pulse duration can be between 1 fs to 1 ms, such as 1 fs to 250 fs, 100 fs to 500 fs, 250 fs to 750 fs, 500 fs to 1 ns, 750 fs to 100 ns, 1 ns to 250 ns, 100 ns to 500 ns, 250 ns to 750 ns, 500 ns to 1000 ns, 750 ns to 1500 ns, 1000 ns to 5000 ns, 1500 ns to 10000 ns, 5000 ns to 100000 ns, 10000 ns to 500000 ns, and 100000 to 1 ms. The laser can be an IR, Green or a UV laser. In certain examples, the laser beam has a width of between about 20 μm and about 50 μm, such as 20-30 μm, 25-40 μm, and 30-50 μm.

In an embodiment, referring to operation 408 and/or operation 412, exposing the metal foil to a laser beam can form a spatter debris on a substrate (e.g., a solar cell). In an example, the presence of this spatter debris feature can inhibit the metal foil from attaching to another material, such as a carrier. Thus, this debris can be removed the metal foil before an subsequent process. In an example, this debris can be removed prior to a subsequent process (e.g., another laser process). In one example, the debris can be removed prior to a bonding of a second material to the metal foil, such as described above with respect to the carrier and or second metal source.

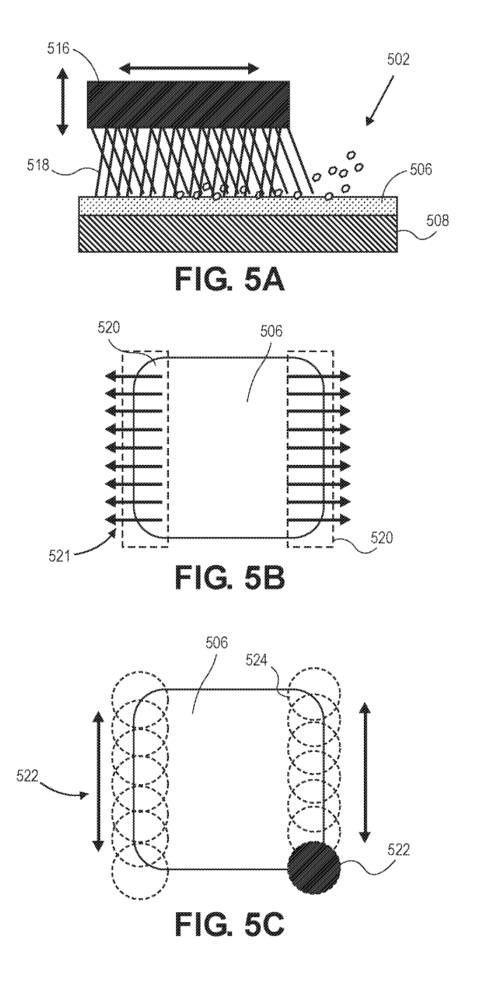

In one embodiment, the substrate metallization system 1000 includes a debris removal unit 1006 adapted to remove debris from a top surface of a metal foil that is attached to a substrate. In one embodiment, the debris removal unit 1006 includes a brush head adapted to remove debris from one or more edge portions of the metal foil attached to one or more edge portions of the solar cell substrate. In one embodiment, the debris removal unit 1006 includes a brush head adapted to remove debris from one or more middle portions of the metal foil attached to one or more middle portions of the solar cell substrate. In one embodiment, the brush head comprises two or more brushes. In one embodiment, the brushes comprise a fiber, such as tampico fiber or other fiber selected for stiffness and reusability that leaves the solar cell substrate substantially damage free. In one embodiment, the debris removal unit 1006 comprises an oscillating brush head. In one embodiment, the debris removal unit 1006 comprises vacuum conveyer belt adapted transport the solar cell substrate past a brush of the oscillating brush head. In an embodiment, the debris removal unit 1006 is controlled by an integrated controller. In another embodiment, the debris removal unit is controlled by the control system 1014. In an example, it was advantageously discovered that a system described in FIGS. 5A-5C, e.g., using one or more brushes, could be used to remove this debris without harming the underlying metal foil, which can be somewhat delicate.

With reference to FIGS. 5A and 5B, in an embodiment, a debris feature 502 is formed on the top surface of a metal foil 506 that has been attached to a solar cell substrate 508. In an example, a brush 516 can used to sweep away or otherwise remove the debris 502, which can be adhered to the top surface of the metal foil 506. In an example, the brush can include bristles 518 which can be used to remove the debris 502. Movement of the brush 516 up and down and/or side to side can allow for the brush 516 to clean, remove or at least partially remove debris from selected portions of the surface of the foil 506.

Referring to FIG. 5B, in an embodiment, a roller brush can be used to clean edge portions 520 of the metal foil 506. The arrows 521 depict the movement of the debris as it is swept from the surface of the metal foil 506. In an example, the substrate can include a solar cell which having a scribe to separate it into two sub-cells, each sub-cells singulated and separated from one another. The sub-cells can be electrically connected, for example with a bridge, such as a electrically conductive bridge.

Referring to FIG. 5C, in an embodiment, an oscillating brush 522 can be used to clean, remove or at least partially remove debris from an edge portion 524 of the metal foil 506 as the substrate is passed by the brush or vice versa, i.e. the brush is passed by the substrate.

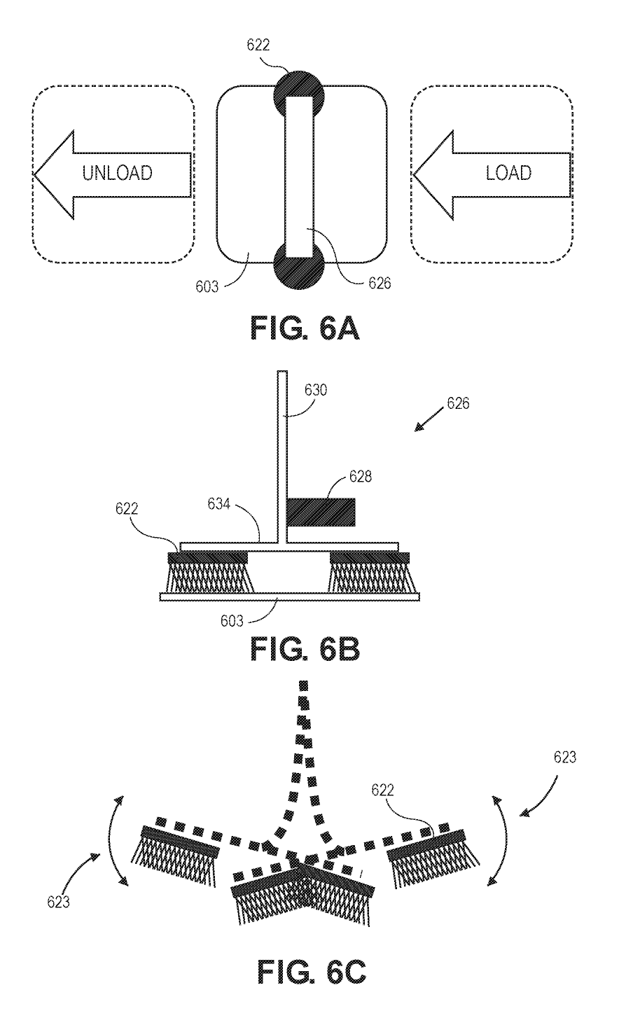

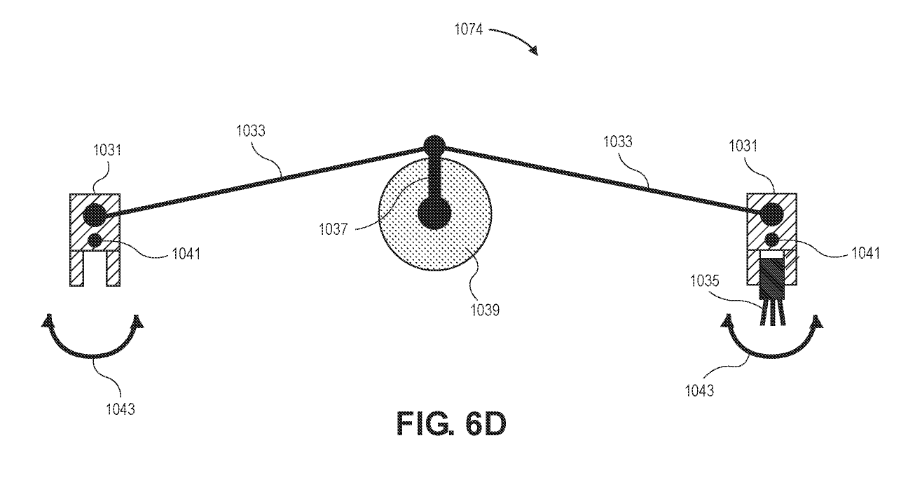

FIG. 6A illustrates a plan view of an oscillating brush design for the removal of debris from a substrate 603 (e.g., a solar cell), in accordance with an embodiment of the present disclosure. As the substrate 603 moves from a load to an unload position, the substrate 603 passes under an oscillating brush head 626. In this example, the brush head 626 includes two brushes 622, which allows for the simultaneous cleaning of the two underlying edge portions of the substrate 603. In an example, a metal foil can be located over the substrate 603 and the brush head, e.g., along with the brushes 622, clean, remove or at least partially remove of debris from the metal foil over the substrate 603.

FIG. 6B illustrates an elevation view of the oscillating brush design of FIG. 6A in accordance with an embodiment of the present disclosure. As shown in FIG. 6B, the oscillating brush head 626 includes an oscillating plate 630 with an oscillating motor/vibrator 628, e.g., fit to provide oscillating motion. In this example, two brushes 622 are fit to a spanner 634 that is attached to the oscillating plate 630. The width of the spanner 622 locates the brushes 662 over the portion of the substrate 603.

Referring to FIG. 6C, the oscillating brush design of FIG. 6A and 6B is shown during a cleaning and/or removal operation is shown. In an embodiment, power can be supplied to the oscillating motor/vibrator 628 causing the brushes 622 to move over the surface of the substrate 603 as shown be the exaggerated arrows and movement 623. Vibration/oscillation frequency, vibration/oscillation force, brush height and work piece throughput can selected to provide for delicate but satisfactory cleaning of the surface of the substrate 603 and/or a metal foil disposed over the substrate 603.

FIG. 6D is a schematic illustration of an alternative oscillating brush system 1074 where individual oscillating brush heads 1031 oscillate. The brush heads 1031 include brushes 1035, that sweep across edges of a substrate (not shown) with reciprocating motion depicted by arrows 1043. The oscillation of the oscillating brush heads 1031 is driven about pivot points 1041 by a motor 1039. Circular motion of the motor 1039 is translated to the reciprocating motion of the brush heads 1031 by link 1037 coupled to second link 1033.

FIG. 7 illustrates a perspective view of an oscillating brush debris removal unit, in accordance with an embodiment of the present disclosure. As shown in FIG. 7, the oscillating brush debris removal unit 734 can include a loading station 736, and an unloading station 738. A vacuum conveyer belt 740 can pass a substrate 738 (e.g., a solar cell) from the loading station 734 to the unloading station 738 and under the oscillating brush head 726 as shown by the arrow 727. As shown the oscillating brush head 726 is connected to the base 741 of the oscillating brush debris removal unit 734 by an arm 742, which holds the oscillating brush head 726 stationary as the substrates 736 are moved or conveyed under oscillating brush head 726. In one embodiment, the brush debris removal unit 734 can be referred to as a debris removal unit. In an example, the brush debris removal unit 734 can remove debris from a metal foil disposed over the substrate 736, e.g., disposed over a solar cell. In one embodiment, the brush debris removal unit 734 unit can include a vacuum chuck adapted to retain the substrate during contact with an oscillating brush 722 of the oscillating brush head 726.

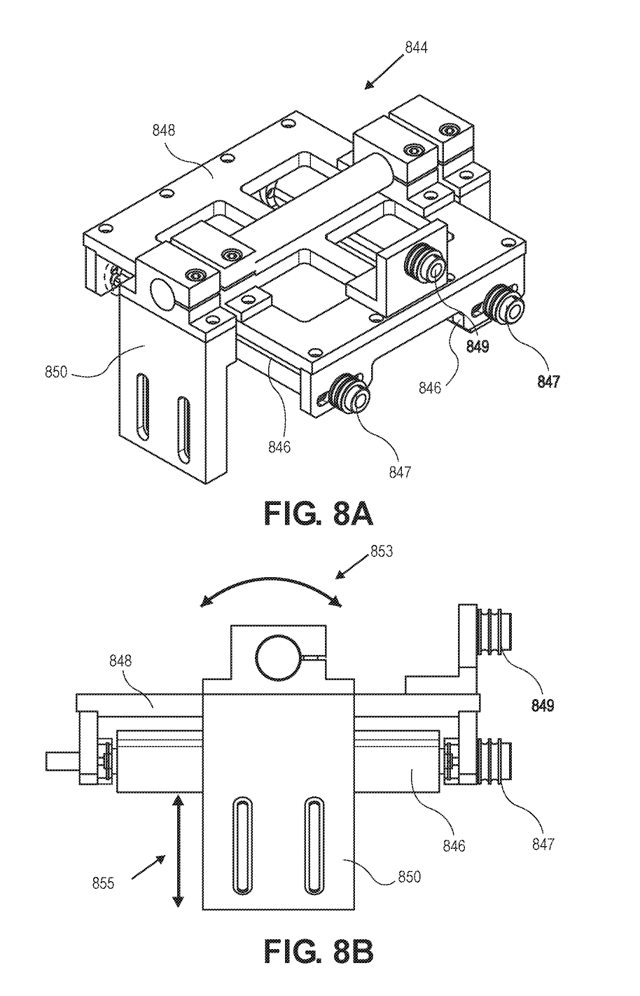

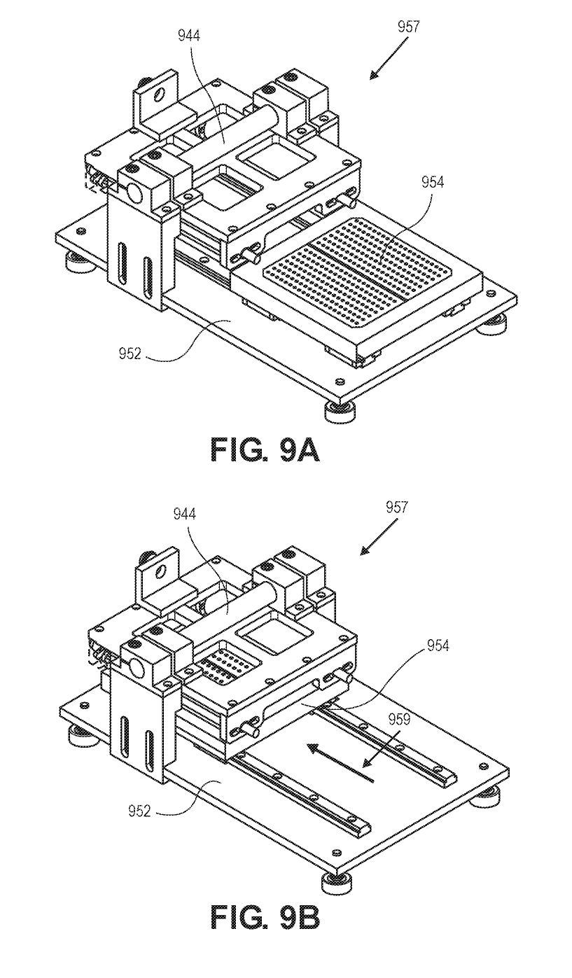

FIG. 8A illustrates a perspective view of a roller brush head for a debris removal unit, in accordance with an embodiment of the present disclosure. In an embodiment, a roller brush head 844 can include two brushes 846 that are held by a carriage 848. In an example, the brushes 846 can include roller brushes, e.g., brushes configured to rotate on a single access, where the brushes can be connected and/or secured to the carriage 848. The roller brushes 846 can be driven by drive pulley 849, connected via a drive belt (not shown) to the slave pulleys 847. The drive pulley 849 can be driven by a motor (not shown). Other implementations are possible, such as meshed gears and/or multiple electric motors. The rotation of the roller brushes 846 is selected to push the debris outward, away from the center of a substrate 803 (e.g., a solar cell). The carriage 848 can be held in place by stanchion 850, for example as shown in FIGS. 9A and 9B.

For clarity FIG. 8B illustrates a side elevation view of the roller brush head of FIG. 8A, in accordance with an embodiment of the present disclosure. As depicted by the arrows 853 and 855 the roller brush head 844 has multiple degrees of freedom and adjustment to select the appropriate pressure and/or contact area for cleaning debris from the surface of a solar cell.

FIGS. 9A and 9B illustrate a perspective views of a roller brush debris removal unit 957, in accordance with an embodiment of the present disclosure. As shown, the roller brush debris removal unit 957 can include a base 952 that is coupled to the roller brush head 944. In an example, the roller brush debris removal unit 957 includes a vacuum chuck 954 that can be used to secure a substrate (e.g., a solar cell) as it is moved under the roller brush head 944. FIG. 9A shows a view prior or after to cleaning, where the vacuum chuck 954 is not under the roller brush head 944. FIG. 9B shows a view where the chuck 954 can be under or below the roller brush head 944, e.g., during a cleaning process, and/or debris removal process as shown by the arrow 959.

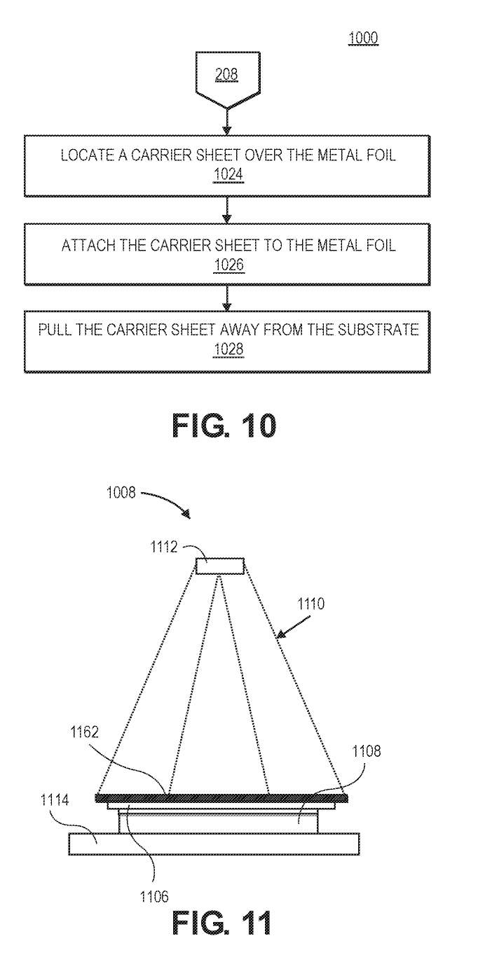

FIG. 10 is a flowchart 1000 representing various operations of removing a portion of the metal foil in operation 208 of the work flow of FIG. 2, for example, using a carrier attachment unit 1008 and a metal removal unit 1010, in accordance with an embodiment of the present disclosure. The carrier attachment unit 1008 and a metal removal unit 1010 can be integrated or separate. At operation 1024, the method involves locating a carrier over the metal foil. At operation 1026, the method involves attaching the carrier to the metal foil. At operation 1028, the method involves pulling the carrier away from the substrate. In an example, pulling the carrier away from the substrate can include removing portions of the metal foil from the substrate.

The carrier attachment unit 1008 is shown in FIG. 11. As shown, the carrier attachment unit 1008 can include a laser source 1112 and a chuck 1114. In an example, a substrate (e.g., a solar cell) 1108 can be located or placed on the chuck 1114. The substrate can include a metal foil 1106 disposed over the substrate. In an example, a carrier 1162 can be located or placed over the metal foil 1106. The substrate, e.g., the laser source 1112 can be used to expose the carrier 1162 to a laser beam 1110, as described in detail below. In an example, the laser beam 1110 can be configured to attach the carrier to the metal foil 1106. In some embodiments, the carrier 1162 can include another metal foil. In an embodiment, the carrier 1162 attachment unit 1008 can be adapted to attach a carrier to a surface of a metal foil 1106. Thus, in an embodiment, a carrier attachment unit 1008 can be adapted to attach a carrier 1162 to the metal foil 1006.

Referring again to FIG. 11, in one embodiment, the carrier attachment 1008 unit is adapted to is adapted to locate a carrier 1162 over the metal foil 1106. In an example, the unit 1008 can include pick and place robot that can place the carrier 1162 over the metal foil 1106. In an example, at the time of locating the carrier 1162 over the metal foil 1106, the carrier 1162 can have a surface area substantially larger than a surface area of the substrate. In one example, prior to placing the carrier 1162 over the substrate 1108, the sheet of carrier 1162 can be cut to a size having a surface area substantially the same as a surface area of the substrate. The carrier 1162 can be laser cut, water jet cut, and the like, for example, prior to or even after placement. In an embodiment, the carrier attachment unit 1008 can include an alignment system to accurately locate the carrier 1162 over the metal foil 1106. In one embodiment, the carrier attachment unit 1008 can include a roller, where the roller can be used to position or locate the carrier 1162 over the metal foil 1106. In an example, similar to the vacuum, the roller can uniformly locate the carrier 1162 over the metal foil 1106, e.g., no air gaps or spaces between the carrier 1162 and the metal foil 1106.

Referring again to FIG. 11, in one embodiment, the carrier attachment unit 1008 can be adapted to expose the carrier 1162 to a laser beam. Thus, in one embodiment, the carrier attachment unit 1008 includes a laser source 1112. In an embodiment, the power, wavelength and/or pulse duration of the laser source 1112 can be selected to bond the carrier 1162 to the metal foil 1106. In an embodiment, the laser has a wavelength of between about 250 nm and about 2000 nm (such as wavelength of 250 nm to 300 nm, 275 nm to 400 nm, 300 nm to 500 nm, 400 nm to 750 nm, 500 nm to 1000 nm, 750 nm to 1500 nm, or 1000 nm to 2000 nm), the laser peak power is above 5×10⁺⁴ W/mm², and the laser is a pulse laser with a pulse frequency of about 1 kHz and about 10 MHz (such as about 1 kHz and about 10 MHz, such a 1 kHz to 1000 kHz, 500 kHz to 2000 kHz, 1000 kHz to 5000 kHz, 2000 kHz to 7500 kHz, or 5000 kHz to 10 mHz. The pulse duration can be between 1 fs to 1 ms, such as 1 fs to 250 fs, 100 fs to 500 fs, 250 fs to 750 fs, 500 fs to 1 ns, 750 fs to 100 ns, 1 ns to 250 ns, 100 ns to 500 ns, 250 ns to 750 ns, 500 ns to 1000 ns, 750 ns to 1500 ns, 1000 ns to 5000 ns, 1500 ns to 10000 ns, 5000 ns to 100000 ns, 10000 ns to 500000 ns, and 100000 to 1 ms. The laser can be an IR, Green or a UV laser. In certain examples, the laser beam has a width of between about 20 μm and about 50 μm, such as 20-30 μm, 25-40 μm, and 30-50 μm.

In an embodiment, the carrier attachment unit 1008 is adapted to scribe or otherwise cut carrier 1162 so that portions of the carrier 1162 not bonded to the metal foil 1106 can be removed. In an embodiment, the carrier attachment unit 1008 is adapted to remove the excess carrier 1162 so scribed and/or cut. In one embodiment, the carrier 1162 is a metal foil, such as a second metal source, such as a metal foil, metal wire or metal tape. In an embodiment, the carrier attachment 1008 unit is adapted to locate the second metal source over the first metal foil 1106. In embodiment, the carrier attachment unit 1008 is adapted to expose the second metal source to a laser beam in selected locations over positions of the first metal foil 1162. Subjecting the second metal source to the laser beam can connect the second metal source to the first metal foil 1106. Removing the second metal source from the substrate can selectively remove regions of the first metal foil 1106 that are not connected to semiconductor regions on the substrate. In an embodiment, the carrier 1162 is further used to provide additional metallization to a substrate, for example to build or provide another or second layer of metal in selected regions of the metallization, such as for the construction of busbars were addition metal thickness could prove useful for conduction of electricity. Thus, in an embodiment, carrier attachment unit is adapted to bond the second metal source to the first metal foil 1106 in selected regions to provide additional metallization in these selected regions. In embodiments, the carrier attachment unit is adapted to pattern the second metal source, for example to increase metal thickness in some regions and to be used as a carrier to remove the first metal foil 1106 in other regions. In another embodiment, this second metallization is done with the optional second LAMP unit 1009.

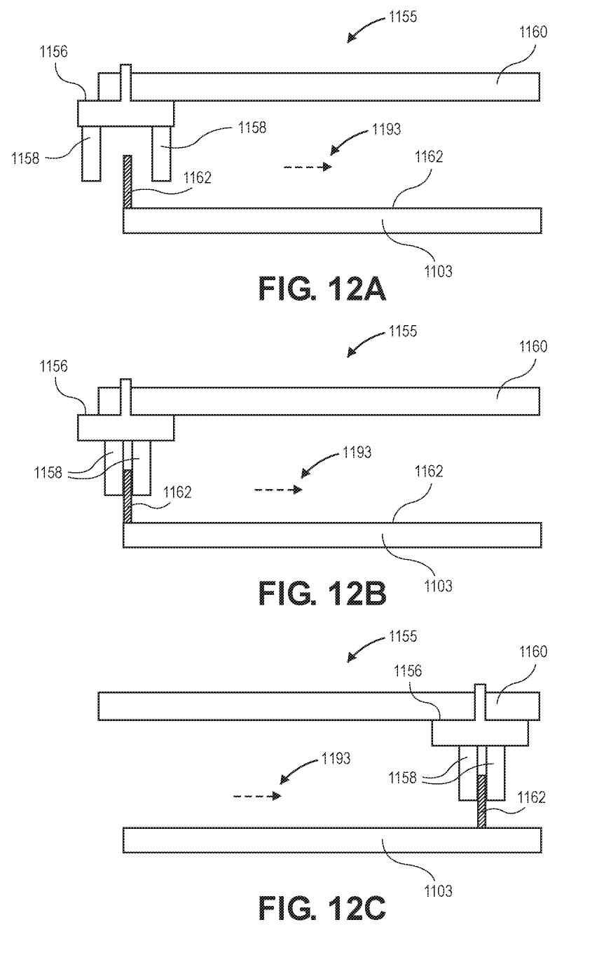

FIGS. 12A-12C illustrates a schematic of a removal unit 1155, in accordance with an embodiment of the present disclosure. As shown in FIGS. 12A-12C clamp system 1155 can include a clamp head 1156 and clamp jaws 1158. The clamp head 1156 can actuate the clamp jaws 1158 to grasp and hold onto an edge of a carrier 1162 (e.g., as described in FIG. 11). In an example, once the edge of a carrier 1162 is held by the clamp jaws of the clamp head 1154, the clamp head 1156 can move along a gantry 1160 as shown by arrow 1193, for example, to pull the edge of a carrier 1162 and metal foil attached to the carrier 1162 along and/or away from a substrate 1103 (e.g., a solar cell). In one embodiment, the metal removal unit can include a vacuum source adapted to remove the portion of the metal foil pulled away from the top surface of the substrate 1103. In an example, at FIG. 12C, the vacuum source can be used to pull away or remove the metal foil. In some examples, the vacuum source can pull away the carrier 1162 or at least portions of the carrier 1162 along with the metal foil.

In an embodiment, in place of or in combination with the clamp system 1155 any other removal tool can be included. In an example, a mandrel can be included in the removal unit 1155. In the same example, the mandrel can collect the carrier and/or metal foil to be removed. In an example, the mandrel can be expanded, rotated and translated (e.g., from one end of a substrate to another) and subsequently retracted to remove the carrier and/or metal foil portions from the substrate.

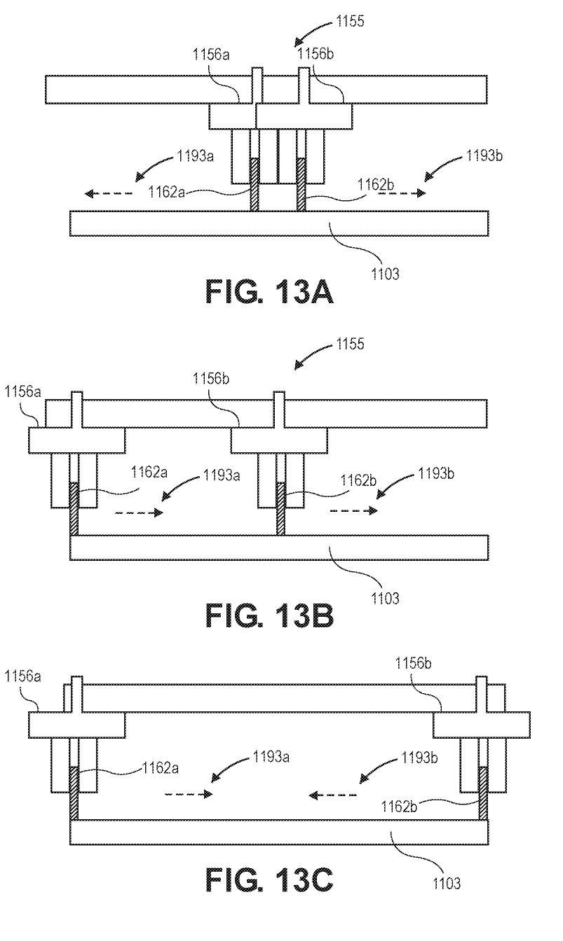

FIGS. 13A-13C illustrate several examples configurations in which two clamps 1156a and 1156b can be used to remove the carrier and attached metal foil. In one embodiment, the metal removal unit can include a first clamp 1156a and a second clamp 1156b, where the first clamp 1156a is adapted to the secure a first edge portion of the carrier 1162a extending from a first edge portion of the substrate 1103 and the second clamp 1156b is adapted to the secure a second edge portion of the carrier 1162b extending from a second edge portion of the substrate opposite the first edge portion of the substrate 1103. In one embodiment, the metal removal unit can include a vacuum source adapted to remove the portion of the metal foil pulled away from the top surface of the substrate.

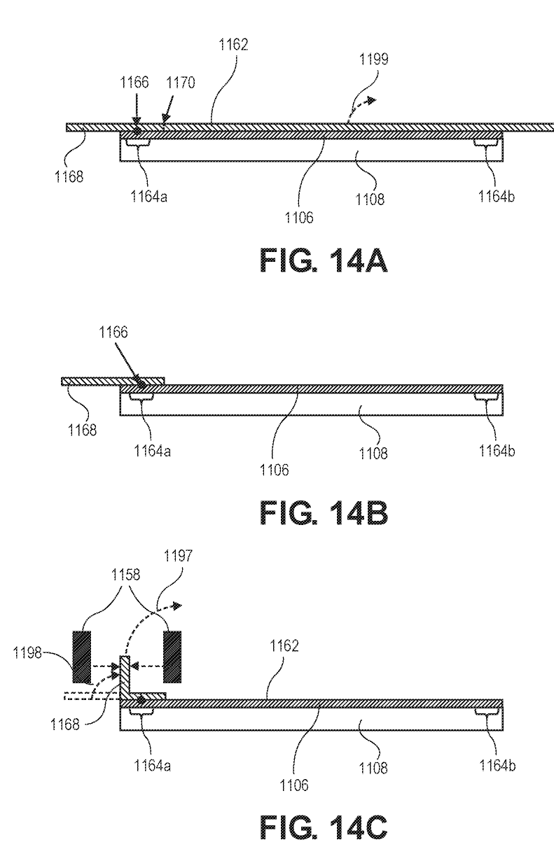

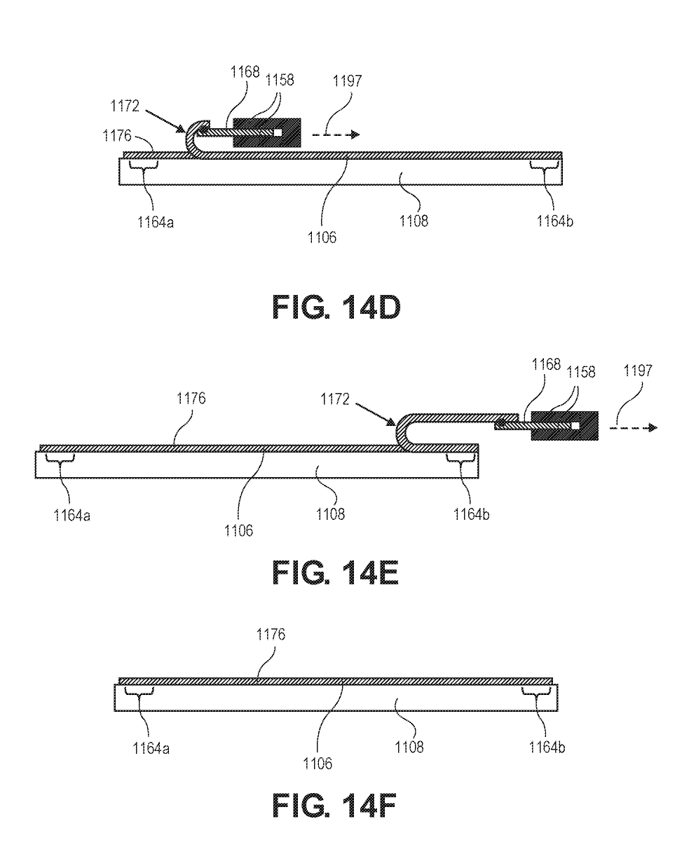

FIGS. 14A-14F illustrate side elevation views of various operations in a method of LAMP of substrates, in accordance with an embodiment of the present disclosure.

In an embodiment, as shown in FIG. 14A, a carrier 1162 is located over a substrate 1108 (e.g., a solar cell). In an example, the substrate include a metal foil 1106 having conductive contact structures including a locally deposited metal portion which is in electrical connection with the substrate 1108. The carrier 1162 can be attached to the metal foil 1106 at position 1166. Also shown are the locations of possible busbars 1164a and 1164b. The carrier 1162 can be scribed, such as laser scribed, at position 1170 so that portions of the carrier can be removed, see dashed arrow 1199, leaving behind an attached portion 1168 of carrier 1162. In an example, a smaller portion of carrier 1166 corresponding to the attached portion 1168 of carrier 1162 can be used, see FIG. 14B.

Turning to FIG. 14C, the attached portion of carrier 1168 can be bent as shown by arrow 1198 to position it to be grasped and/or retained by jaws 1158 of a clamp. In an example, the clamp can be configured to grasp the overhanding attached portion 1168 of carrier 1162. In an example, the bending can be in an angle between 0 and 90 degrees normal to the substrate, such as between 0 degrees and 30 degrees, 15 degrees and 45 degrees, 30 degrees and 60 degrees, 45 degrees and 75 degrees, or 60 degrees and 90 degrees. The attached portion 1168 can be pulled away as shown by arrow 1197 to remove metal from the substrate 1108. Jaws 1158 may be textured, coated, or otherwise treated to increase the coefficient of friction.

Turning to FIGS. 14D and 14E, once the attached portion 1168 of the carrier is securely grasped and/or retained by the clamp the attached portion 1168 of carrier 1162 and the attached metal foil 1106 can be pulled or drawn away from the substrate 1108. In an example, pulling away the attached metal foil can effectively remove foil 1172 while leaving behind the metal 1176 attached to the substrate 1108 with conductive contact structure including a locally deposited metal portion that is in electrical connection with the substrate 1108 to form the structure as shown in FIG. 14F.

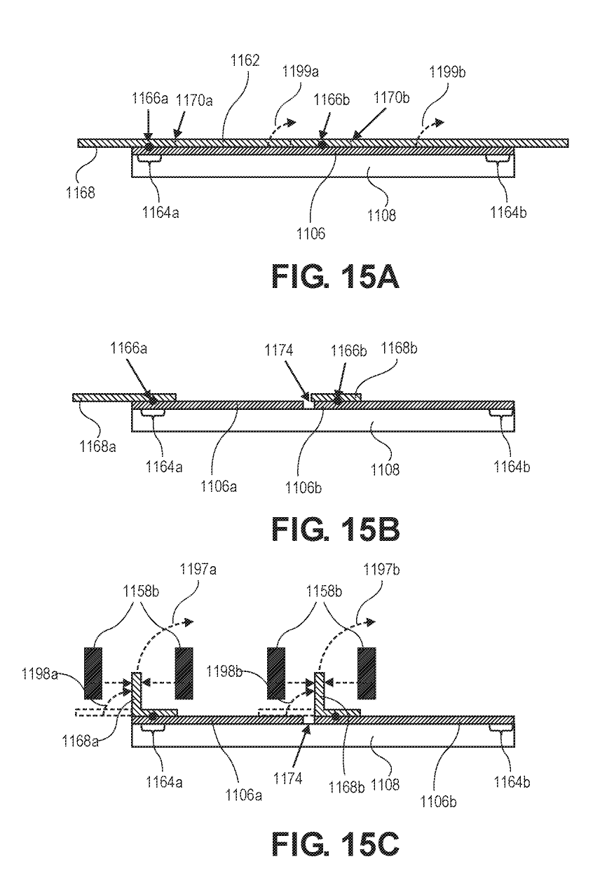

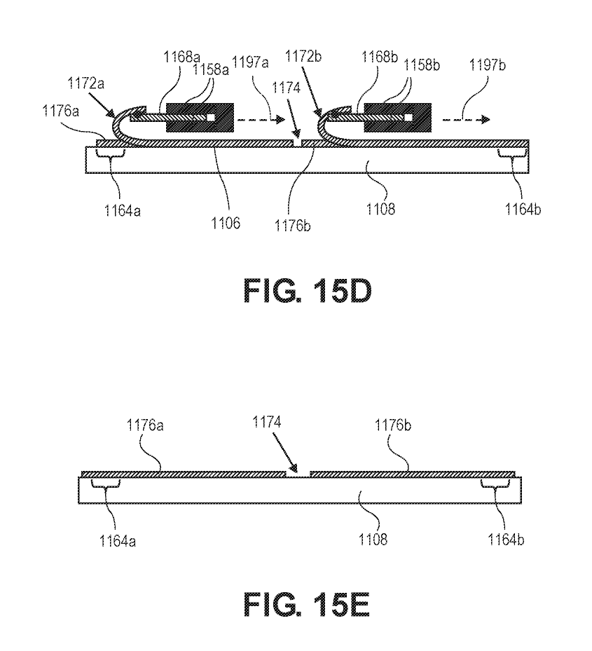

FIGS. 15A-15E illustrate side elevation views of various operations in a method of LAMP of substrates, in accordance with an embodiment of the present disclosure. As distinguished from the embodiment shown in FIGS. 14A-14F two clamps can be used, for example to pull the portions of metal foil from two sub cells on a substrate.

As shown in FIG. 15A a carrier 1162 can be located over a metal foil 1106 that has been attached to the substrate 1108 by a conductive contact structure including a locally deposited metal portion that is in electrical connection with the solar cell substrate 1108. In an example, the carrier 1162 is attached to the metal foil 1106 at positions 1166a and 1166b over two sub cells, respectively. Also shown are the locations of possible busbars 1164a and 1164b. The carrier can be scribed, such as laser scribed, at positions 1170a and 1170b so that portions of the carrier can be removed, see dashed arrow, leaving behind an attached portion 1168a and 1168b of carrier 1162. In an example, a smaller portion of carrier corresponding to the attached portion 1168a and 1168b of carrier 1162 can be used. The metal foil 1106 attached to the substrate 1108 can have conductive contact structures including a locally deposited metal portion that is in electrical connection with the substrate 1108. In an example, the substrate 1108 can be scribed, such as laser scribed, at position 1174 to divide the substrate 1108 into to two sub-cells, see FIG. 15B. The underlying substrate can also be scribed in the same or other operation.

Turning to FIG. 15C, the attached portions 1168a and 1168b of carrier can be bent as shown by arrows 1198a and 1198b to position it to be grasped by clamp jaws 1158a and 1158b of two clamps. In an example, the clamp can be configured to grasp the overhanding attached portions 1168a and 1168b of carrier 1162. The attached portions 1168a and 1168b can be pulled away as shown by arrows 1197a and 1197b to remove metal from the substrate 1108.

Turning to FIG. 15D, portions 1168a and 1168b of the carrier can be held or grasp of the jaws 1158a and 1158b the attached portions 1168a and 1168b of carrier 1162 and the attached foil can be pulled or drawn away from the solar cells substrate 1108. This effectively removes portions of the foil 1172a and 1172b while leaving behind the metal foil 1176a and 1176b that has been attached to the substrate 1108 conductive contact structure including a locally deposited metal portion that is in electrical connection with the substrate, see FIG. 15E.

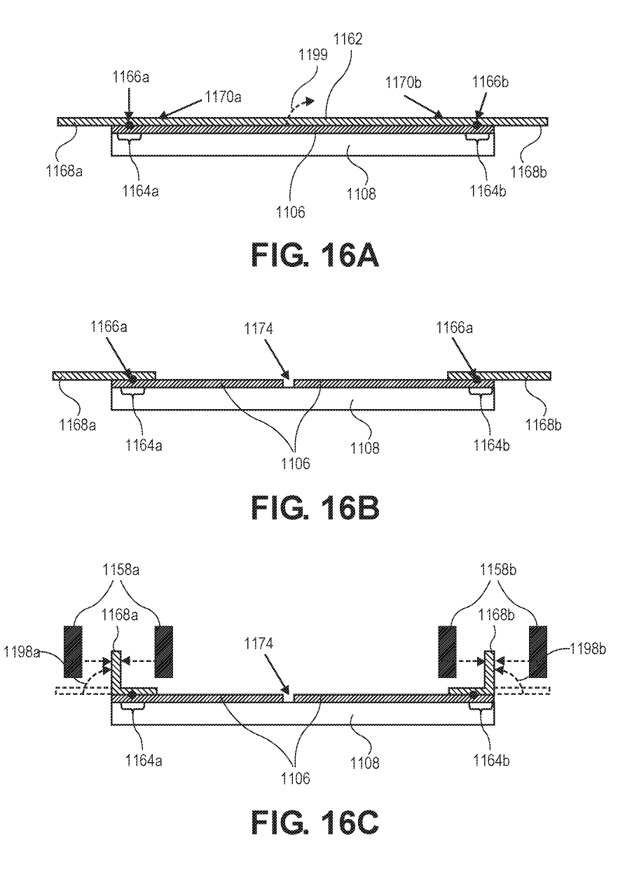

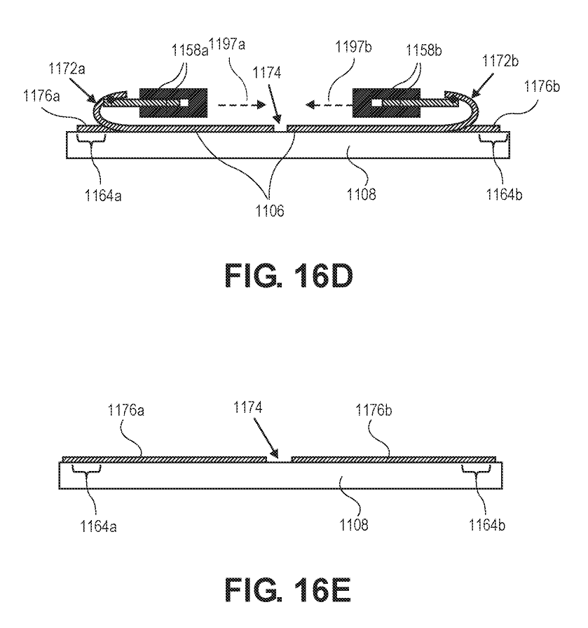

FIGS. 16A-16E illustrate side elevation views of various operations in a method of LAMP of substrates, in accordance with an embodiment of the present disclosure. As distinguished from the embodiment shown in FIGS. 15A-15E the two clamps used pull in opposite directions to pull the excess foil from two sub cells on a single solar cell substrate.

As shown in FIG. 16A a carrier 1162 is located over a substrate 1108 that includes a metal foil 1106 that has been attached to the solar cells substrate 1108 by a conductive contact structure including a locally deposited metal portion that is in electrical connection with the solar cell substrate 1108. The carrier 1162 is attached to the metal foil 1106 at positions 1166a and 1166b for the two sub cells respectively. Also shown are the locations of possible bus bars 1164a and 1164b. The carrier can be scribed, such as laser scribed, at positions 1170a and 1170b so that portions of the carrier can be removed, see dashed arrow, leaving behind an attached portion 1168a and 1168b of carrier 1162. In an example, a smaller portion of carrier corresponding to the attached portion 1168a and 1168b of carrier 1162 can be used. The metal foil 1176 that has been attached to the solar cell substrate 1108 conductive contact structure including a locally deposited metal portion that is in electrical connection with the solar cell substrate 1108 can be scribed, such as laser scribed, at position 1174 to divide the two sub cells, see FIG. 16B.

Turning to FIG. 16C, the attached portions 1168a and 1168b of carrier can be bent as shown to position it to be grasped by clamp jaws 1158a and 1158b of two clamps. Alternatively the clamp can be configured to grasp the overhanding attached portions 1168a and 1168b of carrier 1162. The attached portions 1168a and 1168b can be pulled away as shown by arrows 1197a and 1197b to remove metal from the substrate 1108.

Turning to FIG. 16D once the attached portions 1168a and 1168b of the carrier are in the grasp of the jaws 1158a and 1158b the attached portions 1168a and 1168b of carrier 1162 and the attached foil can be pulled or drawn away from the solar cells substrate 1108. This effectively removes excess foil 1172a and 1172b while leaving behind the metal foil 1176a and 1176b that has been attached to the solar cell substrate 1108 conductive contact structure including a locally deposited metal portion that is in electrical connection with the substrate, see FIG. 16E.

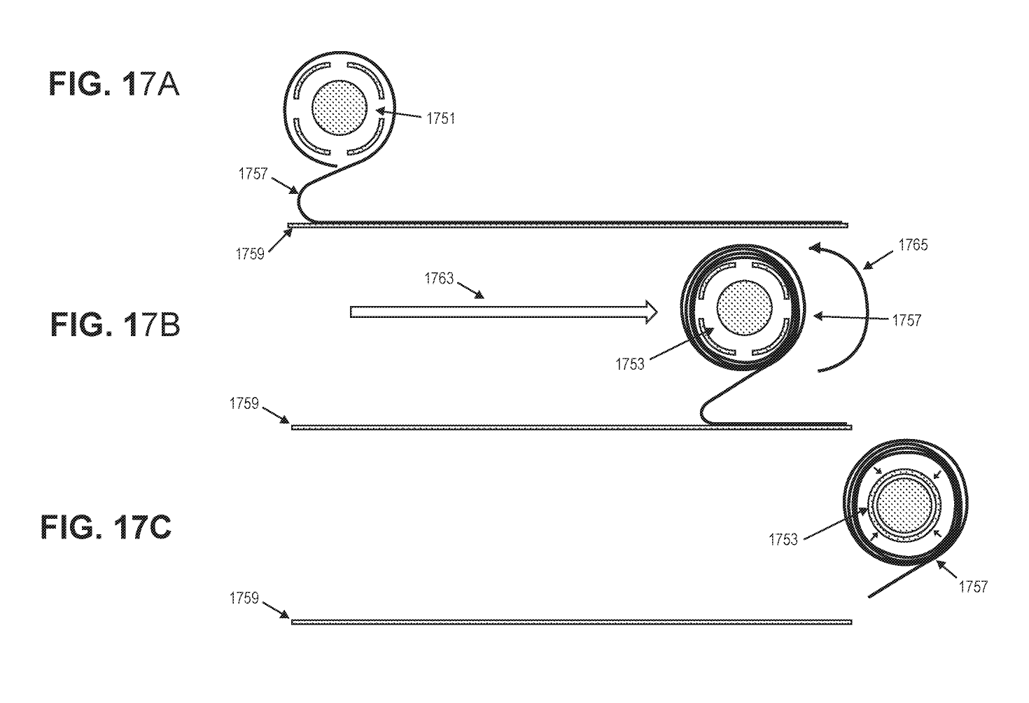

Turning to FIGS. 17A-17C, in an embodiment, a mandrel 1751 can be included in the metal removal unit. Referring to 17A, the mandrel 1751 can collect the carrier and/or metal foil portions 1757 to be removed, where the carrier and/or metal foil 1757 can be located over a substrate 1759. Referring to 17B, the mandrel can be expanded 1753, rotated 1765 and translated 1763 (e.g., from one end of the substrate 1759 to another end as shown). Referring to 17C, the mandrel 1751 can be retracted to remove the carrier and/or metal foil portions 1757 from the substrate 1759.

Although certain materials are described specifically with reference to above described embodiments, some materials can be readily substituted with others with such embodiments remaining within the spirit and scope of embodiments of the present disclosure. For example, in an embodiment, a different material substrate, such as a group III-V material substrate, can be used instead of a silicon substrate. In another embodiment, any type of substrate used in the fabrication of micro-electronic devices can be used instead of a silicon substrate, e.g., a printed circuit board (PCB) and/or other substrates can be used. Additionally, although reference is made significantly to back contact solar cell arrangements, it is to be appreciated that approaches described herein can have application to front contact solar cells as well. In other embodiments, the above described approaches can be applicable to manufacturing of other than solar cells. For example, manufacturing of light emitting diode (LEDs) can benefit from approaches described herein.

Additionally, although solar cells are described in great detail herein, the methods and/or processes described herein can apply to various substrates and/or devices, e.g., semiconductor substrates. For example, a semiconductor substrate can include a solar cell, light emitting diode, microelectromechanical systems and other substrates.

Furthermore, although many embodiments described pertain to directly contacting a semiconductor with a metal foil as a metal source. Concepts described herein can also be applicable to solar applications (e.g., HIT cells) where a contact is made to a conductive oxide, such as indium tin oxide (ITO), rather than contacting a semiconductor directly. Additionally, embodiments can be applicable to other patterned metal applications, e.g., PCB trace formation.

Thus, local metallization of semiconductor substrates using a laser beam, and the resulting structures are presented.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A system for the metallization of a substrate, comprising:
a laser assisted metallization patterning unit adapted to expose a metal foil located over a substrate to a laser beam to form a conductive contact structure comprising a locally deposited metal on the substrate;
a carrier attachment unit adapted to attach a carrier to the metal foil; and
a metal removal unit adapted to remove the carrier and at least a portion of the metal foil.

2. The system of claim 1, further comprising:
a debris cleaning unit adapted to remove debris from a surface of a metal foil that is attached to a substrate;

3. The system of claim 2, wherein the debris removal unit comprises brush head with two or more brushes.

4. The system of claim 3, wherein the brushes comprise tampico fiber.

5. The system of claim 2, wherein the debris removal unit comprises an oscillating brush head.

6. The system of claim 5, wherein the debris removal unit comprises vacuum conveyer belt adapted transport the substrate past a brush of the oscillating brush head.

7. The system of claim 2, wherein the debris removal unit comprises a roller brush head.

8. The system of claim 7, wherein the debris removal unit comprises vacuum chuck adapted to retain the substrate during contact with a roller brush of the roller brush head.

9. The system of claim 1, wherein the carrier attachment unit is adapted to attach a carrier to one or more edge portions of the metal foil.

10. The system of claim 1, wherein the carrier attachment unit is adapted to attach a carrier to one or more middle portions of the metal foil.

11. The system of claim 1, wherein the metal removal unit comprises one or more clamps adapted to secure one or more edge portions of a carrier extending from the metal foil and pull the portion of the metal foil away from the substrate.

12. The system of claim 11, wherein the metal removal unit comprises a first clamp adapted to the secure a first edge portion of the carrier extending from a first edge portion of the substrate

13. The system of claim 11, wherein the metal removal unit comprises a second clamp, wherein the second clamp is adapted to the secure an second edge portion of the carrier extending from a middle edge portion or second edge portion of the substrate.

14. The system of claim 11, wherein the metal removal unit comprises a vacuum source adapted to remove the portion of the metal foil pulled away from the top surface of the substrate.

15. The system of claim 1, wherein the laser assisted metallization patterning unit comprise one or more laser sources.

16. The system of claim 1, further comprising a second laser assisted metallization patterning unit adapted to bond a second metal source to metal foil located over a substrate to the metal foil located over a substrate.

17. The system of claim 1, wherein the second laser assisted metallization patterning unit comprise one or more laser sources.

18. A system for the metallization of a substrate, comprising:
a means for laser assisted metallization patterning of a substrate;
a means for attaching a carrier to the top surface of the metal foil; and
a means for removing the carrier and at least a portion of the metal foil from the top surface of a substrate.

19. The system of claim 18, further comprising:
a means for removing debris from a top surface of a metal foil that is attached to a substrate.

20. The system of claim 19, further comprising
a means to bond a second metal source to a metal foil located over a substrate to the metal foil located over a substrate.
